(19) United States
(12) Patent Application Publication
(10) Pub. No.: US 2007/0273003 A1
(43) Pub. Date: Nov. 29, 2007

(54) SEMICONDUCTOR DEVICE AND MANUFACTURING METHOD THEREOF

(75) Inventor: Jong-Taek Hwang, Seoul (KR)

Correspondence Address: LOWE HAUPTMAN HAM & BERNER, LLP, 1700 DIAGONAL ROAD, SUITE 300, ALEXANDRIA, VA, 22314, US

(73) Assignee: DONGBU HITEK CO., LTD., Seoul (KR)

(21) Appl. No.: 11/751,362

(22) Filed: May 21, 2007

(30) Foreign Application Priority Data
May 24, 2006 (KR) 10-2006-0046605

(51) Int. Cl. H01L 29/00; H01L 21/31; H01L 21/469

(52) U.S. Cl. 257/531; 438/788

(57) ABSTRACT

A semiconductor device and a method of manufacturing the semiconductor device is provided. The method includes the steps of forming a first insulating layer on a top surface of a semiconductor substrate having a plurality of patterns, immediately before gaps between the patterns are completely closed; forming a lower insulating film by isotropically etching the first insulating layer for a specific amount of time, such that aspect ratios of the gaps between the patterns are reduced; forming a second insulating layer on the lower insulating film such that the gaps between the patterns are completely filled with the second insulating film; and forming an upper insulating film by planarizing the second insulating layer.

### FIELD OF THE INVENTION

The present invention relates to a manufacturing method of a semiconductor device; and, more particularly, to a semiconductor device in which gaps between patterns formed on a semiconductor substrate are filled with an insulating layer, and a manufacturing method thereof.

### BACKGROUND OF THE INVENTION

As the design rule becomes smaller due to the increase of the integration density of semiconductor devices, gap filling becomes more difficult, in which an insulating material is deposited for the purpose of electrical insulation between the devices. Therefore, a chemical vapor deposition (CVD) method having a satisfactory gap filling characteristic has been used.

FIGS. 1A through 1C are cross-sectional views illustrating a gap filling method using a conventional CVD method.

Referring to FIGS. 1A through 1C, a plurality of patterns 13 are formed on a semiconductor substrate 11 at a predetermined interval as shown in FIG. 1A, an insulating layer 15 is deposited on a top surface of the semiconductor substrate 11 through a CVD method such that gaps between the patterns 13 are filled with the insulating layer 15 as shown in FIG. 1B, and an insulating film 15a is then formed by planarizing the insulating layer 15 as shown in FIG. 1C.

Meanwhile, in pre-metal dielectric (PMD) gap filling, TEOS-ozone based borophosphosilicate glass (hereinafter, referred to as “BPSG”), with which gaps in a desired portion can be filled through heat treatment such as annealing using densification and reflow characteristics after deposition, is used as the insulating layer 15. The insulating layer 15 is formed by depositing a BPSG layer on the semiconductor substrate 11 having the patterns 13 formed as a gate layer through a CVD method, and the insulating film 15a that is a PMD layer is formed by reflowing the BPSG layer through a heat treatment process.

However, in accordance with the conventional gap filling method described above, since a reflow property of the BPSG is satisfactory when the aspect ratio of a gap is about 5:1 or less, it does not matter. However, since it is difficult to fill gaps when the aspect ratio of a gap is large, voids 1 are formed in the insulating film 15a as shown in FIGS. 1B and 1C. Since an amount of the oxide layer deposited on a bottom of a gap with a broad width is large when an interval between the patterns 13 is broad, the voids 1 are not produced although the oxide layer is redeposited on a sidewall portion of the pattern. However, since an amount of the oxide layer deposited on a bottom of a gap with a narrow width is a little when an interval between the patterns 13 is narrow, the voids 1 are produced due to the oxide layer redeposited on the sidewall portion of the pattern.

When such voids exist between gates, there is a problem in that a leakage current is generated, and thus the reliability of a device is degraded.

### SUMMARY OF THE INVENTION

Therefore, the present invention is directed to providing a semiconductor device wherein gaps between patterns formed on a semiconductor substrate is filled with an insulating layer without voids, and a manufacturing method of the semiconductor device.

Above, in accordance with one aspect of the present invention, there is provided a method of manufacturing a semiconductor device, including the steps of forming a first insulating layer on a top surface of a semiconductor substrate having a plurality of patterns, immediately before gaps between the patterns are completely closed; forming a lower insulating film by isotropically etching the first insulating layer for a specific amount of time, such that aspect ratios of the gaps between the patterns are reduced; forming a second insulating layer on the lower insulating film such that the gaps between the patterns are completely filled with the second insulating film; and forming an upper insulating film by planarizing the second insulating layer.

In accordance with another aspect of the present invention, there is provided a semiconductor device including a semiconductor substrate having a plurality of patterns formed thereon; a lower insulating film partially filling gaps between the patterns to reduce aspect ratios of the gaps; and an upper insulating film formed on the lower insulating film to completely fill the gaps between the patterns.

### BRIEF DESCRIPTION OF THE DRAWINGS

The above and other objects and features of the present invention will become apparent from the following description of preferred embodiments given in conjunction with the accompanying drawings, in which:

FIGS. 1A through 1C are cross-sectional views illustrating a conventional method of manufacturing a semiconductor device; and

FIGS. 2A through 2E are cross-sectional views illustrating a method of manufacturing a semiconductor device in accordance with the present invention.

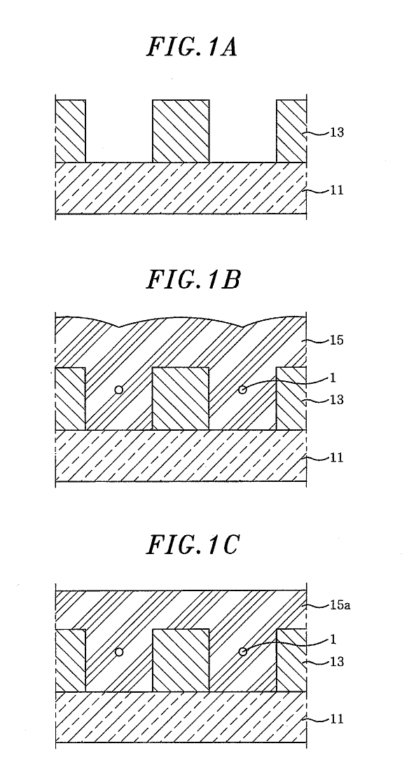

### DETAILED DESCRIPTION OF THE EMBODIMENTS

Hereinafter, preferred embodiments of the present invention will be described in detail with reference to the accompanying drawings so that they can be readily implemented by those skilled in the art.

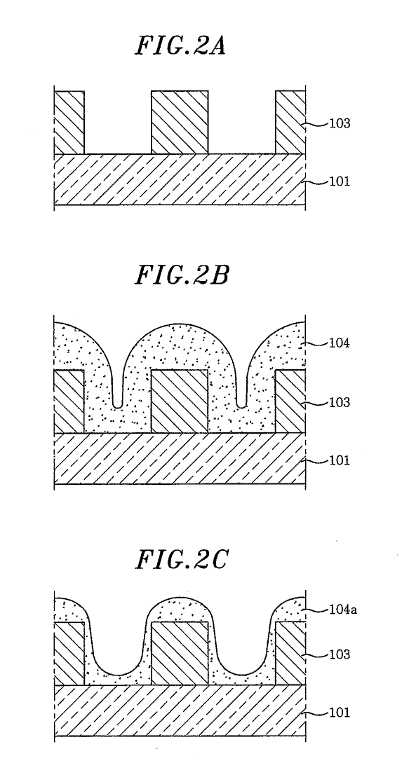

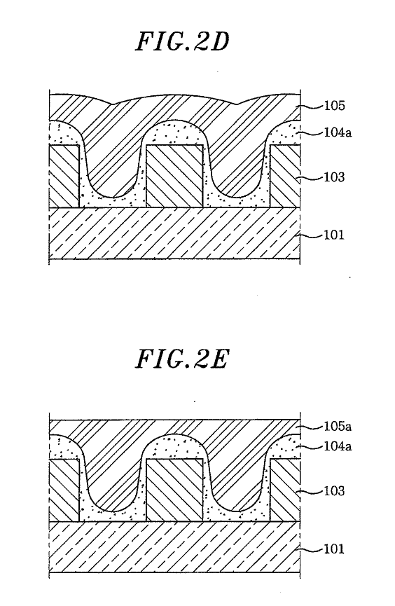

FIGS. 2A through 2E are cross-sectional views illustrating a method of manufacturing a semiconductor device in accordance with the present invention. A method of manufacturing a semiconductor device according to the present invention, particularly a gap filling process, will be described below.

First, a plurality of patterns 103 are formed on a semiconductor substrate 101 at a predetermined interval as shown in FIG. 2A, and a first insulating layer 104 is formed on a top surface of the semiconductor substrate 101 immediately before gaps between the patterns 103 are completely closed as shown in FIG. 2B. That is, the first insulating layer 104 is formed immediately before overhangs are completely closed by the first insulating layer 104 such that the gaps between the patterns 103 are changed to have a narrow and deep shape. Here, it is preferred that the first insulating layer 104 be deposited using a thermal CVD method with conformability superior to other CVD methods.

Thereafter, as shown in FIG. 2C, a lower insulating film 104a for reducing the aspect ratios of the gaps between the patterns 103 are formed by performing an isotropic wet etching with respect to the first insulating layer 104 for a specific amount of time. Here, it is preferred that the first insulating layer 104 be etched with a dilute HF (DHF) solution. At this time, since the DHF solution penetrates into the gaps with a narrow and deep shape between the patterns 103, a sidewall portion of each of the gaps is removed more than a lower portion thereof.

Next, as shown in FIG. 2D, a second insulating layer 105 is formed on the lower insulating film 104a such that the gaps between the patterns 103 are completely filled with the second insulating layer 105. Here, it is preferred that the second insulating layer 105 be deposited using a high-density plasma CVD method having an excellent gap filling ability.

Finally, as shown in FIG. 2E, an upper insulating film 105a is formed by planarizing the second insulating layer 105. Thus, the gaps between the patterns 103 are completely filled with an insulating film including the lower and upper insulating films 104a and 105a, without voids.

Meanwhile, in PMD gap filling, TEOS-ozone based BPSG having excellent conformability is used as the first insulating layer 104. Specifically, the semiconductor substrate 101 having the patterns 103 formed as a gate layer is loaded into a thermal CVD apparatus and then moved into a deposition chamber. The first insulating layer 104 is deposited by supplying N₂ and He gases into the deposition chamber using TEOS and O₃ as reaction substances. Preferably, the O₃ of 4500 to 5500 scc, TEOS of 900 to 1100 mgm, N₂ gas of 6300 to 7700 scc and He gas of 1800 to 2200 scc are supplied. Preferably, a heating substrate is heated at about 480° C. such that the semiconductor substrate 101 is maintained at about 440° C. More preferably, O₃ of 5000 scc, TEOS of 1000 mgm, N₂ gas of 7000 scc and He gas of 2000 scc are supplied. The first insulating layer 104 is deposited in a thickness of 800 to 1200 Å, and a time required in the deposition is set as 40 to 50 seconds. Here, a deposition stop time is determined by determining a deposition time through a pre test and then stopping the deposition at the corresponding time.

When forming the lower insulating film 104a by partially etching the first insulating layer 104, a DHF solution in which H₂O and HF are diluted at a ratio of 200 to 1 is used, and the first insulating layer 104 is wet-etched for 3 to 10 seconds. At this time, the first insulating layer 104 is etched by 800 to 600 Å to remain with a thickness of 200 to 400 Å at the sidewall portion of each of the gaps. The first insulating layer 104 is etched by 600 to 400 Å to remain with a thickness of 400 to 600 Å at the lower portion of each of the gaps. Meanwhile, the partial etching of the first insulating layer 104 may be performed through other etching methods under a condition that isotropic etching is performed. For example, the partial etching of the first insulating layer 104 may be performed through wet etching using a buffered oxide etchant (BOE) solution.

The process of forming the second insulating layer 105 for the upper insulating film 105a is performed through a high-density plasma CVD method. In one embodiment, the second insulating layer is deposited for 40 to 50 seconds while SiH₄ and O₂ gases are supplied. An undoped silicate glass (USG) layer is deposited through a method in which high-density plasma is produced using SiH₄ and O₂ as a plasma source. That is, SiO₂ formed with SiH₄ and O₂ is deposited on the lower insulating film 104a, and O₂ particles are drawn onto a surface of the lower insulating film 104a by applying RF bias power to a back side thereof. Then, gap filling is performed while sputter etching occurs together with deposition. At this time, the deposition is performed for 30 to 45 seconds, LF power is applied by 3150 to 3850 W, HF power is applied by 2205 to 2695 W, and a deposition temperature is maintained at 250 to 400° C. Preferably, the LF power is applied by 3500 W, and the HF power is applied by 2450 W.

When forming the upper insulating film 105a by planarizing the second insulating layer 105, a chemical mechanical polishing (CMP) process is used.

If the gap filling process described above has been finished, a semiconductor device in which the gap filling is performed by the lower and upper insulating films 104a and 105a without voids is manufactured as shown in FIG. 2E. The structure of the semiconductor device will be discussed. As shown in FIG. 2E, the semiconductor devices includes a semiconductor substrate 101 on which a plurality of patterns 103 are formed at a predetermined interval; a lower insulating film 104a with which gaps between the patterns 103 are partially filled to reduce the aspect ratio of the gap; and an upper insulating film 105a formed on the lower insulating film 104a to completely fill the gaps between the patterns 103. Particularly, the thickness of the lower insulating film 104a in each of the gaps between the patterns 103 will be discussed. Since, the lower insulating film 104a has a thickness of 200 to 400 Å at a sidewall portion of the gap, and has a thickness of 400 to 600 Å at a lower portion thereof, the lower portion of each of the gaps is thicker than the sidewall portion thereof. The lower insulating layer 104a reduces the aspect ratios of the gaps between the patterns 103. Accordingly, a gap filling characteristic of the second insulating layer 105 for the upper insulating film 105a is improved, and thus voids are not formed in the second insulating layer 105.

As described above, in the present invention, a lower insulating film is first formed in gaps between patterns formed on a semiconductor substrate so as to reduce the aspect ratio of the gap, and gap filling is completed using an upper insulating film, so that a gap filling characteristic is improved, and thus voids are not produced. Accordingly, there is an advantage in that a leakage current between gates is previously prevented from being generated due to voids, so that reliability of a device can be enhanced.

While the invention has been shown and described with respect to the preferred embodiments, it will be understood by those skilled in the art that various changes and modifications may be made without departing from the scope of the invention as defined in the following claims.

What is claimed is:

1. A method of manufacturing a semiconductor device, comprising the steps of:
(a) forming a first insulating layer on a top surface of a semiconductor substrate having a plurality of patterns, immediately before gaps between the patterns are completely closed;
(b) forming a lower insulating film by isotropically etching the first insulating layer for a specific amount of time, such that aspect ratios of the gaps between the patterns are reduced;
(c) forming a second insulating layer on the lower insulating film such that the gaps between the patterns are completely filled with the second insulating film; and
(d) forming an upper insulating film by planarizing the second insulating layer.

2. The method of claim 1, wherein, in step (a), the first insulating layer is deposited for 40 to 50 seconds while TEOS, O₃, and N₂ and He gases are supplied by using a thermal CVD method.

3. The method of claim 1, wherein, in step (b), the first insulating layer is wet-etched for 3 to 10 seconds by using a DHF solution.

4. The method of claim 1, wherein, in step (c), the second insulating layer is performed by using a high-density plasma CVD method.

5. The method of claim 1, wherein, in step (c), the second insulating layer is deposited for 40 to 50 seconds while SiH₄ and O₂ gases are supplied.

6. A semiconductor device comprising:
a semiconductor substrate having a plurality of patterns formed thereon;
a lower insulating film partially filling gaps between the patterns to reduce aspect ratios of the gaps; and
an upper insulating film formed on the lower insulating film to completely fill the gaps between the patterns,
wherein the lower insulating film has a thickness of 200 to 400 Å at a sidewall portion, and has a thickness of 400 to 600 Å at a lower portion in each of the gaps between the patterns.

7. The semiconductor device of claim 6, wherein the lower insulating film includes TEOS-ozone based BPSG as a main component thereof.

8. The semiconductor device of claim 6, wherein the lower insulating film is formed by wet-etching an insulating layer deposited by a thermal CVD method.
